(19) United States
(12) Patent Application Publication
(10) Pub. No.: US 2025/0224470 A1
(43) Pub. Date: Jul. 10, 2025

(54) Magnetic Resonance Apparatus and Method

(71) Applicants: Pedro Freire SILVA, Berlin (DE); Felix KREIS, Berlin (DE); Richard REZNICEK, Leipzig (DE); Scott SELTZER, Houston, TX (US); DeepSpin GmbH, Berlin (DE)

(72) Inventors: Pedro Freire SILVA, Berlin (DE); Felix KREIS, Berlin (DE); Richard REZNICEK, Leipzig (DE); Scott SELTZER, Houston, TX (US)

(21) Appl. No.: 18/853,344

(22) PCT Filed: Apr. 3, 2023
(86) PCT No.: PCT/US2023/017300

§ 371 Date: Oct. 1, 2024

(30) Foreign Application Priority Data
Apr. 1, 2022 (LU) LU501776

(51) Int. Cl. G01R 33/38; G01R 33/36

(52) U.S. Cl. CPC G01R 33/3808; G01R 33/3664; G01R 33/3804

(57) ABSTRACT

A nuclear magnetic resonance coil and method of using a magnetic resonance coil, the coil configured to, in a first mode, receive at a drive port and conduct a current for generating a static magnetic field in a space adjacent to the coil and, in a second mode, receive and output to a receive port a nuclear magnetic resonance signal generated in said space.

### FIELD

Embodiments described herein generally relate to magnetic resonance apparatus. More specifically, embodiments described herein relate to magnetic resonance apparatus and methods in which a coil used for receiving magnetic resonance signal also serves to provide a polarising quasi-static magnetic field.

### BACKGROUND

Known magnetic resonance apparatus generate a static magnetic field using either a coil or a permanent magnet. The static magnetic field is intended to be homogenous over a volume of interest. A separate, electrically independent coil is used to detect a magnetic resonance signal generated in the volume of interest.

### BRIEF DESCRIPTION OF THE DRAWINGS

FIG. 1 illustrates an NMR system according to an embodiment;

FIG. 2 illustrates an activation sequence for coils used in an embodiment;

FIG. 3A illustrates spin polarisation under the influence of the field B₀_{ₚᵣₑₚₒₗₐᵣᵢₛₑ};

FIG. 3B illustrates spin polarisation under the influence of the field B₀_{ₘₑₐₛᵤᵣₑₘₑₙₜ};

FIG. 3C illustrates spin polarisation behaviour following the application of the field B₁;

FIG. 4 shows a coupling circuitry for a dual use coil;

FIG. 5 shows another coupling circuitry for a dual use coil;

FIG. 6 illustrates a cross section of an axisymmetric simulation of a dual use coil of an embodiment;

FIG. 7 shows the properties of a material used in a magnetic core of an embodiment;

FIG. 8A is a schematic illustration, showing right half cross-sectional view of an axisymmetric NMR system according to an embodiment;

FIG. 8B is a 3-dimensional isometric projection of an NMR system according to an embodiment;

FIG. 8C is a close-up view of part of the NMR system shown in FIG. 8a;

FIG. 9A illustrates a dual use coil separated into multiple parts, according to an embodiment;

FIG. 9B illustrates a circuit for connecting coils L1 to L4 of a dual use coil according to an embodiment;

FIG. 10A and 10B illustrate cross sections of a 2-dimensional axisymmetric simulation of the safety exclusion zone for embodiments of the NMR system with (FIG. 10b) and without (FIG. 10a) a counter coil and a magnetic structure;

FIG. 11 is a schematic illustration of an interdigitated arrangement for the passive cooling element 1010 and the magnetic structure 1020 of the NMR system, according to an embodiment;

FIG. 12 is a schematic illustration that shows a cross section of the dual use coil 1110, according to an embodiment.

FIG. 13 shows a simulated temperature profile of the bed, magnetic structure and dual use coil 1110 over the course of 7 measurement cycles, according to an embodiment;

FIG. 14 illustrates the temperature distribution of the simulated NMR system shown in FIG. 13 at time=3.725 hr;

FIG. 15 shows the result of a simulation of coil sensitivity spatial profiles, according to an embodiment;

FIGS. 16a and 16b show the result of a simulation of the loss of SNR of the NMR signal using active noise cancellation, without and with a gap, respectively:

FIG. 17 illustrates a magnetic structure according to an embodiment;

FIGS. 18a and 18b shows the eddy current back field resulting from the casing top of the metal enclosure 1702, without and with a passive coil 1802, respectively, according to an embodiment; and

FIG. 19 shows the eddy current back field resulting from eddy currents propagating in the casing top of the metal enclosure below the dual use coil, in the presence of a magnetic structure but in the absence of a passive coil, according to an embodiment.

### DETAILED DESCRIPTION

According to embodiments there is provided a nuclear magnetic resonance coil, configured to, in a first mode, receive at a drive port and conduct a current for generating a static magnetic field in a space adjacent to the coil and, in a second mode, receive and output to a receive port a nuclear magnetic resonance signal generated in said space. The first and second modes are consecutive to each other.

In an embodiment the coil comprises a plurality of inductors, wherein all of the inductors of the plurality of inductors are used when generating the static magnetic field but only a subset or only one of the inductors of the plurality of inductors is used for sensing an NMR signal. The plurality of inductors may be discretely provided or may share the same winding core.

In an embodiment only a subset of inductors of the plurality of inductors or only one inductor of the plurality of inductors that are/is closest to a patient contact surface of the coil and/or that is closest to a centre line of the coil are/is used for sensing the NMR signal.

In an embodiment the coil comprises a plurality of inductors that are electrically connected in series for a DC current and electrically connected such that, during signal reception the signal is not amplified by the plurality of inductors that do not form part of the subset or only one of the inductors of the plurality of inductors.

In an embodiment the coil comprises an electric circuit electrically isolating the drive port and the receive port from each other.

In an embodiment, the coil is dimensioned so as to generate the static magnetic field in a volume of interest that permits acquiring nuclear magnetic resonance (NMR) signals throughout the depth of a torso or other body part of an adult human subject located prone or supine on a face of the coil.

In an embodiment, the NMR signals are magnetic resonance imaging (MRI) signals.

In an embodiment, the electric circuit is a passive circuit.

According to another embodiment there is provided a nuclear magnetic resonance coil, wherein the coil comprises a ferromagnetic core surrounded by windings of the coil. In an embodiment, the nuclear magnetic resonance coil is a nuclear magnetic resonance coil as hereinbefore described, i.e. a nuclear magnetic resonance coil that is configured to operate at the described first mode and the described second mode.

In an embodiment, an amplification of the NMR signal voltage received by the coil is amplified by a factor of 20 or less, preferably by a factor 5 or less. Put in other words, in this embodiment the amplification applied to a received NMR signal is low. This is advantageous in situation where the entirety of the dual use coil described herein is used for signal reception.

In another embodiment in which only a smaller portion of the dual use coil is used for signal reception the NMR signal voltage received by the coil is amplified by a factor of 1000 or more.

In another embodiment, the coil is non-resonant.

In another embodiment, it is used a standard amplified coil in MRI.

In another embodiment, the self-resonance frequency of the coil is chosen so that the highest Larmor frequency to be observed is close to the self-resonance frequency of the coil whilst maintaining a high sensitivity of incoming signal. In an embodiment, the self-resonance frequency of the coil is chosen so that the highest Larmor frequency to be observed using the coil is no higher than 0.9 times, preferably no higher than 0.8 times, the self-resonance frequency of the coil.

According to another embodiment there is provided a nuclear magnetic resonance coil, comprising a patient side, adjacent to which a patient is to be located during a magnetic resonance examination and soft ferromagnetic shielding on at least one side of the coil other than the patient side. In an embodiment, the nuclear magnetic resonance coil is a coil as described hereinbefore.

According to another embodiment there is provided a nuclear magnetic resonance apparatus comprising a static magnetic field driver, a receive chain and nuclear magnetic resonance coil as claimed in any of the preceding claims.

In an embodiment the nuclear magnetic resonance apparatus further comprises a static magnetic field coil configured to, when energised, generate a static magnetic field substantially orthogonal to the static magnetic field generated by the nuclear magnetic resonance coil in a region of interest of the apparatus and a driver for driving the static magnetic field coil. In the embodiment, the nuclear magnetic resonance apparatus is configured to adiabatically switch between the static magnetic field generated by the nuclear magnetic resonance coil and the static magnetic field generated by the static magnetic field coil.

In the embodiment, the region of interest is located on a patient side of and at a distance of 20 cm from a patient facing front face of the nuclear magnetic resonance coil.

In an altemative embodiment, the static magnetic field that is substantially orthogonal to the static magnetic field generated by the nuclear magnetic resonance coil is not generated by a coil but is instead generated by a permanent magnet that does not need to be selectively energised. It will be appreciated that, in this embodiment, the prepolarising field is the sum of the static magnetic field generated by the nuclear magnetic resonance coil and the static magnetic field generated by the permanent magnet. In one embodiment, this sum may be dominated by the static magnetic field generated by the nuclear magnetic resonance coil to a degree that the summed field is still substantially orthogonal to the static magnetic field generated by the permanent magnet. For example, the static magnetic field generated by the nuclear magnetic resonance coil may be 200 mT in a predetermined location in the coil's volume of interest, whilst the static magnetic field generated by the permanent magnet may have a strength of 1 mT. In another embodiment, the static magnetic field generated by the nuclear magnetic resonance coil and the static magnetic field generated by the permanent magnet have relative strength such that the sum of both fields are no longer substantially orthogonal to the static magnetic field generated by the permanent magnet. For example, the relative strength of the fields may be such that the sum of the fields is inclined by 45 to 135 degrees relative to the direction of the static magnetic field generated by the permanent magnet. In this example, the sum of the fields has a considerably higher magnitude than the field generated solely by the nuclear magnetic resonance coil, hence achieving a higher degree of prepolarisation. It will be appreciated that, even in this example the magnetisation will precede around the direction of the static magnetic field generated by the permanent magnet during the acquisition of nuclear magnetic resonance signal. As the geometry of the nuclear magnetic resonance coil is unaffected by the choice of a permanent magnet for creating the measurement static magnetic field the nuclear magnetic resonance coil is equally sensitive to this signal.

According to another embodiment there is provided a nuclear magnetic resonance coil comprising a ferromagnetic core and coil windings wound around the ferromagnetic core.

In an embodiment the ferromagnetic core comprises a plurality of contacting ferromagnetic components that are electrically insulated from each other.

In an embodiment the components are electrically insulated from each other by an insulator extending in a radial plane that includes a longitudinal axis of the coil.

In an embodiment the coil system comprises a first coil as described above that has a first diameter and a first longitudinal axis. The system further comprises a second coil with a second diameter and a second longitudinal axis, wherein the first and second longitudinal axes substantially coincide and wherein the second diameter is larger than the first diameter, the first and second coils arranged so that at a distance from the longitudinal axis that is greater than the second diameter, the second coil generates a field that counteracts the field generated by the first coil.

In an embodiment the coil system further comprises flux guiding components arranged to guide the magnetic flux generated by the second coil away from the longitudinal axes.

In an embodiment the flux guiding components comprise one or more or all of:
a flux guiding plate arranged below the second coil and having footprint contiguous with the second coil or protruding beyond the second coil either or both of radially inwardly and radially outwardly;
a flux guiding plate between the first and second coil, preferably adjacent and radially inwardly of the second coil;
a flux guiding plate configured to extend in a deployed position from a point at or beyond the maximum diameter of the second coil, in a radially outward direction as well as in a direction from the first coil towards an region of interest.

In an embodiment the flux guiding plate that is configured to extend in a radially outward direction as well as in a direction from the first coil towards an region of interest is further configured to be moved to a stowed away position in which the flux guiding plate no longer extends in the radially outward direction from the point at or beyond the maximum diameter of the second coil.

In an embodiment the flux guiding plate that is configured to extend in a radially outward direction as well as in a direction from the first coil towards an region of interest is planar and is hingedly connected to the point at or beyond the maximum diameter of the second coil.

In an embodiment the coil system is further configured, to energise and/or de-energise the first and second coil simultaneously.

In an embodiment the second coil has better sensitivity to noise sources in the far field than the first coil.

In an embodiment, the ferromagnetic material is ferrite.

In an embodiment preferred ferromagnetic materials include those that have a resistivity of above 10⁻Ωm and/or a relative permeability of >100 and/or Q=mμ′/mμ″ of >10 or, more preferably of Q=mμ′/mμ″ of >100. Any ferromagnetic materials having any of the possible combinations of these properties are suitable for use in embodiments.

According to another embodiment there is provided a magnetic resonance method comprising generating a first static magnetic field in an area of interest using a coil by applying a current through the coil, discontinuing application of the current flowing through the coil, generating a second static magnetic field in the area of interest, applying a radiofrequency magnetic field to the area of interest at a frequency based on the strength of the second static magnetic field in the area of interest and receiving any nuclear magnetic resonance signal generated in the area of interest.

In an embodiment the discontinuing of the application of the current to the coil and the generating of the second static magnetic field is performed such that, in a region of interest of a magnetic resonance apparatus performing the method, an adiabatic switching between a static magnetic field generated by the current flowing the coil and the second static magnetic field is performed. It will be appreciated that, in an embodiment, this switching is achieved by at least a partial overlap between a ramp-down of the current flowing to the coil and a ramp-up of a current in a coil that generates the second static magnetic field.

In an embodiment, the nuclear magnetic resonance signal is acquired simultaneously with the application of the radiofrequency magnetic field.

According to an embodiment there is provided a nuclear magnetic resonance coil system comprising a coil on a ferromagnetic core, wherein the ferromagnetic core has a plurality of spokes, each extending below the coil from a centre below the coil to a radial end at a radial distance that exceeds a diameter of the coil, some or each spoke of the plurality of spokes further extending upwardly from the radial end to form an upwardly extending part outside of a maximum diameter of the coil. Gaps between the spokes and/or between the upwardly extending parts comprise a material that has a thermal conductivity that exceeds the thermal conductivity of the ferromagnetic core.

In an embodiment the material that has a thermal conductivity that exceeds the thermal conductivity of the ferromagnetic core is further provided above the coil and/or in a centre of the coil.

In an embodiment the coil comprises a longitudinal axis and a plurality of layers stacked in the longitudinal axis and/or a plurality of windings adjacent each other in a radial direction, wherein the coil further comprises a material that has a thermal conductivity that exceeds the thermal conductivity of windings of the coil and/or the thermal conductivity of the ferromagnetic core.

According to an embodiment there is provided a magnetic resonance system comprising an first coil having a longitudinal axis and sensitive to radiofrequency signals emanating from a region of interest as well as to electromagnetic noise emanating outside of the region of interest, the system further comprising a noise cancellation coil having a longitudinal axis that substantially coincides with the longitudinal axis of the coil, the noise cancellation coil sensitive to electromagnetic noise emanating outside of the region of interest; the system configured to sense noise emanating outside of the region of interest and subtract it from signal received by the first coil using a predetermined scaling factor.

In an embodiment a ferromagnetic shield positioned to reduce the sensitivity of the noise cancellation coil to signals emanating from the region of interest.

In one embodiment a ratio of a sensitivity to background noise of the noise cancellation coil relative to the sensitivity to background noise of a coil used for sensing NMR signals, such as the dual use coil, is desirable greater than one.

In an embodiment a ratio of a sensitivity to NMR signals of the noise cancellation coil relative to the sensitivity to NMR signals of a coil used for sensing NMR signals, such as the dual use coil, is desirable lower, desirably far lower than one.

In an embodiment a sensitivity of the noise cancellation coil to a far field noise source is higher than a sensitivity of the first coil.

In an embodiment the system comprises a second noise cancellation coil. The second noise cancellation coil has a sensitivity profile that allows sensing of noise in a spatial area in which the noise cancellation coil is insufficiently sensitive to allow cancellation of noise detected by the first coil. Noise sensed by the second noise cancellation coil is subtracted from signal received by the first coil using a second predetermined scaling factor.

In an embodiment the predetermined scaling factor and/or the second predetermined scaling factor is a scaling factor determined using experimental determination of the relative sensitivities of the first coil and the noise cancellation coil. In another embodiment the predetermined scaling factor and/or the second predetermined scaling factor is a scaling factor determined using simulation to determine the relative sensitivities of the first coil and the noise cancellation coil

According to an embodiment there is provided a NMR system comprising a coil configured to generate a time varying magnetic field, a conductive structure and a passive coil located between the coil and the conductive structure, wherein the conductive structure is located within a time varying magnetic field that would be generated by the coil in the absence of the passive coil, wherein the passive coil is positioned in the time varying magnetic field so that the time varying magnetic field induces a current in the passive coil, wherein the passive coil comprises a variable resistance.

In an embodiment, the variable resistance is configured to present a resistance to the coil that allows an eddy current to form and thereafter a higher resistance that dissipates the eddy current.

In an embodiment, the variable resistance is configured to present an initial resistance to the coil that allows an eddy current to form and thereafter a higher resistance that dissipates the eddy current. In an embodiment the variable resistance is gradually increased from its initial resistance to the higher resistance.

According to an embodiment there is provided a method of operating an NMR system comprising using a coil to generate a time varying magnetic field, wherein a passive coil is located between the coil and a conductive structure, wherein the conductive structure is located within a time varying magnetic field that would be generated by the coil in the absence of the passive coil, wherein the passive coil is positioned in the time varying magnetic field so that the time varying magnetic field induces a current in the passive coil, the method comprising varying the resistance of the passive coil to dampen or stop an eddy current flowing in the coil after the eddy current has developed.

In an embodiment, the variable resistance is configured to present an initial resistance to the coil that allows an eddy current to form and thereafter an open circuit that prevents eddy current flow in the passive coil. Preferably a voltage limiting circuit that allows the energy stored in the passive coil to dissipate is also provided.

In an embodiment there is provided a method of operating any of the above described coils or systems.

According to another embodiment there is provided a nuclear magnetic resonance coil or a method of operating the nuclear magnetic resonance coil, the nuclear magnetic resonance coil configured to alternately generate a static magnetic field and to receive nuclear magnetic resonance signals, the coil comprising a conductor and a cooling arrangement configured to flow cooling fluid past the conductor.

In an embodiment, the conductor is provided in a fluid conduit and wherein the coil is arranged to flow the fluid through the fluid conduit.

In an embodiment, the coil comprises a pump that pumps the fluid through the conduit.

In an embodiment, the conductor is a tube and wherein the fluid flows inside of a lumen of the tube.

In an embodiment, at least a part of the conductor is placed in a fluid tight container comprising the fluid.

In an embodiment, the conductor forms windings, wherein the windings are spaced apart from each other, so that the fluid can circulate between adjacent windings.

It was realised that, in known magnetic resonance apparatus, numerous coils compete to maximise the field strength generated in a volume of interest or to maximise their sensitivity to magnetic resonance signal generated in the volume of interest respectively. In the following, a magnetic resonance apparatus that mitigates this competition for magnetic or electromagnetic access to a volume of interest by using a single coil for the purpose of generating a pre-polarising static magnetic field in a volume of interest as well as for sensing magnetic resonance signal generated in the volume of interest is disclosed.

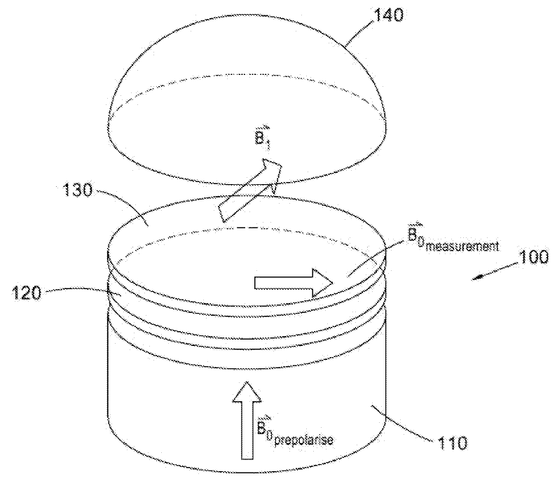

FIG. 1 illustrates an NMR system 100 according to an embodiment. The NMR system 100 comprises a dual use coil 110 for creating a static magnetic field, B₀_{ₚᵣₑₚₒₗₐᵣᵢₛₑ}. This field is shown to extend in the vertical direction in FIG. 1, although this is not essential. As is described further below, the dual use coil 110 can be energised and de-energised so that the field B₀_{ₚᵣₑₚₒₗₐᵣᵢₛₑ} can be activated and deactivated accordingly.

The system 100 further comprises two coils 120 and 130. The coil 120 also generates a static magnetic field, B₀_{ₘₑₐₛᵤᵣₑₘₑₙₜ}. As can be seen from FIG. 1, this field extends substantially orthogonally to the field B₀_{ₚᵣₑₚₒₜₐᵣᵢₛₑ}. As is the case for dual use coil 110, the coil 120 can be energised and de-energised so that the field B₀_{ₘₑₐₛᵤᵣₑₘₑₙₜ} can be activated and deactivated accordingly.

The coil 130 creates a B₁ radio frequency (RF) magnetic field at the precession frequency generated by the field B₀_{ₘₑₐₛᵤᵣₑₘₑₙₜ}. The B₁ field extends substantially orthogonally to B₀_{ₚᵣₑₚₒₗₐᵣᵢₛₑ} as well as to the field B₀_{ₘₑₐₛᵤᵣₑₘₑₙₜ}. As is also the case for known NMR RF coils the B₁ field can be activated and deactivated.

The dual use coil 110 and the two coils 120 and 130 are configured so that the magnetic fields B₀_{ₚᵣₑₚₒₗₐᵣᵢₛₑ}, B₀_{ₘₑₐₛᵤᵣₑₘₑₙₜ} and B₁ are generated in a space occupied by an object 140, such as a patient, that is to be made the subject of the NMR measurement.

In an embodiment, B₀_{ₚᵣₑₚₒₗₐᵣᵢₛₑ} may vary between about 50 mT and about 300 mT within the space 140. In an embodiment, B₀_{ₘₑₐₛᵤᵣₑₘₑₙₜ} may be about 1 mT within the space 140. In an embodiment, B₀_{ₘₑₐₛᵤᵣₑₘₑₙₜ} may be about 2 mT within the space 140.

Whilst a particular configuration of the system 100 is shown in FIG. 1, the spatial arrangements of the magnet and coils shown in FIG. 1 is not essential. In the illustrated embodiment the generated magnetic fields are substantially mutually orthogonal to each other. In another embodiment the directions of the two fields are aligned. It will equally be understood that, whilst dual use coil 110 and coils 120 and 130 are illustrated in FIG. 1 as being spaced apart by gaps, theses gaps are only shown for illustrative purposes and that any or all gaps shown may be omitted in a physical implementation of the illustrated system 100 or that some or all of the dual use coil 110 and coils 120 and 130 may instead be provided in a single unit. In one example, the coils 120 and 130 may form part of a single printed circuit board (PCB).

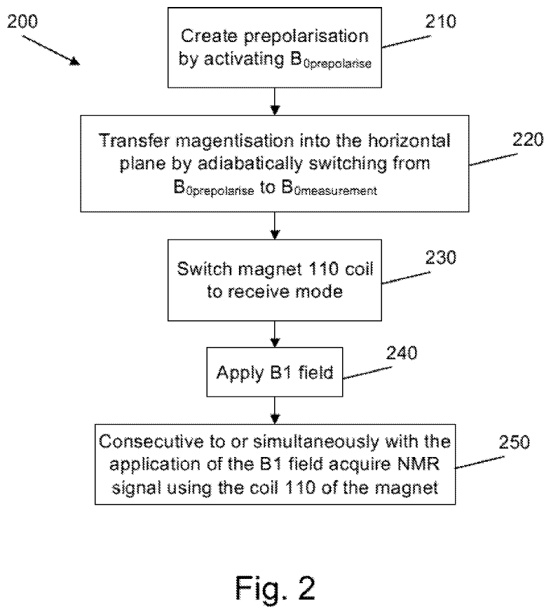

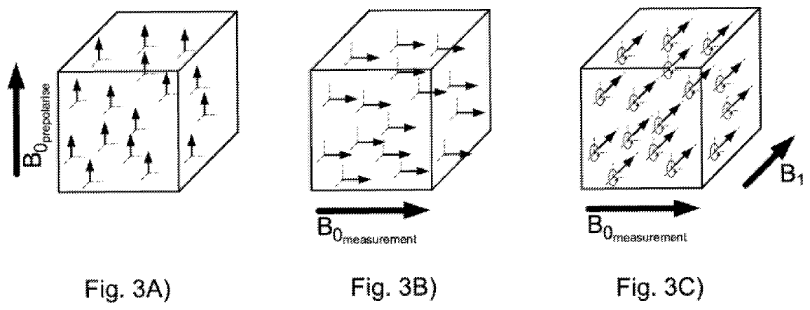

FIG. 2 illustrates an activation sequence 200 for the dual use coil 110 and coils 120 and 130. FIGS. 3A) to 3C) illustrate the change in the state of the polarisation vectors resulting from the various state of the fields applied. In an initial step 210, the dual use coil 110 is energised so that the B₀_{ₚᵣₑₚₒₗₐᵣᵢₛₑ} field is generated as shown in FIG. 3A). The duration for applying the field B₀_{ₚᵣₑₚₒₗₐᵣᵢₛₑ} can be chosen to accommodate desired imaging parameters. For example, if generating T1 contrast is to be avoided, then the field B₀_{ₚᵣₑₚₒₗₐᵣᵢₛₑ} may be applied for a duration that exceeds the longest T1 expected in a 350 sample to be investigated. If T1 contrast between different spin species is to be generated then B₀_{ₚᵣₑₚₒₗₐᵣᵢₛₑ} is applied for a duration that is smaller than the T1 relaxation time of one spin species but larger than the T1 relaxation time of the other spin species. As is well known, a static magnetic field applied to spin species causes the magnetisation to form as illustrated by the arrows shown in FIG. 3A). In a step 220, the dual use coil 110 is deactivated and the coil 120 is activated. As discussed above, the respective static magnetic fields B₀_{ₚᵣₑₚₒₗₐᵣᵢₛₑ} and B₀_{ₘₑₐₛᵤᵣₑₘₑₙₜ} created by the dual use coil 110 and the coil 120 extend substantially orthogonally to each other. The deactivation of the dual use coil 110 and the activation of the coil 120 take place in a short timeframe, in particular in a time t<<T₁, wherein T₁ is the shortest longitudinal relaxation time associated with either B₀_{ₚᵣₑₚₒₗₐᵣᵢₛₑ} or B₀_{ₘₑₐₛᵤᵣₑₘₑₙₜ} (as T1 is a function of field intensity), so that the polarisation generated by the field B₀_{ₚᵣₑₚₒₗₐᵣᵢₛₑ} is transferred to the horizontal plane in alignment with B₀_{ₘₑₐₛᵤᵣₑₘₑₙₜ}. The switch of the magnetisation from alignment with the field B₀_{ₚᵣₑₚₒₗₐᵣᵢₛₑ} to alignment with the field B₀_{ₘₑₐₛᵤᵣₑₘₑₙₜ} is shown in FIG. 3B) and takes place without precessing, so that the constituents forming the net magnetisations remain in phase with each other. This is known as an adiabatic pulse/transfer/switch.

As the dual use coil 110 is de-energised at the end of step 220 it can now be switched to a receive mode in step 230. In an embodiment, once the dual use coil 110 is in receive mode the RF B₁ field can be applied in step 240. This tilts the magnetisation vectors towards a plane that is substantially orthogonal to the direction of the field, B₀_{ₘₑₐₛᵤᵣₑₘₑₙₜ}, with magnetisation precessing about the direction of the field B₀_{ₘₑₐₛᵤᵣₑₘₑₙₜ}, as shown in FIG. 3C). As the dual use coil 110 has created a field in the direction shown in FIG. 3A), the dual use coil 110 is sensitive to the precessing magnetisation vectors shown in FIG. 3C), so that the dual use coil 110 can be used to detect the magnetic resonance signal generated in this manner. By using an electromagnet for generating the B₀_{ₚᵣₑₚₒₗₐᵣᵢₛₑ} field, the intensity, direction and duration of the prepolarising field can be altered by changing the current applied to the dual use coil. This allows measuring different T1 weighted MR signals in combination with gradients, providing images that have an intensity variation corresponding to the longitudinal relaxation time T1 of the tissue that gives rise to the magnetic resonance signal. In one embodiment, the prepolarising field is applied for a time that exceeds the expected T1 in the tissue, so that the acquired signal is maximised. Conversely, in another embodiment, the prepolarising field may be applied for a shorter period of time. This comes at the cost of signal intensity but also reduces the time required for longitudinal relaxation, providing the ability to perform subsequent prepolarisation and associated imaging steps more rapidly than would be possible if the prepolarising field was activated for longer than T1.

In another embodiment, images are acquired for different current amplitudes being used in generating the prepolarising field. With the resulting variation in the intensity of the prepolarising field between images, the image contrast also varies between images as a function of T1.

The difference in the respective populations of the n⁻ and n⁺ spin states of a nucleus with spin ½ at a given field strength B, and a given temperature T can be expressed as:

$$\frac{{n}^{-}}{{n}^{+}} = {e}^{\frac{- Δ E}{kT}} = {e}^{\frac{- γ ℏ {B}_{0}}{kT}}$$

where ΔE is the energy difference between two nuclear spin states, γ is the gyromagnetic ratio of the spin and ℏ is the reduced Planck constant. It will therefore be appreciated that, at a constant temperature, the difference in spin population increases with increasing static magnetic field strength B₀. An increasing difference in the spin populations means that a greater net magnetisation is available for the generation of magnetic resonance signal.

The coil of the dual use coil 110 can carry a considerably higher current than coil 120. As a result, the pre-polarising field B₀_{ₚᵣₑₚₒₗₐᵣᵢₛₑ} has a higher field strength than the measurement field B₀_{ₘₑₐₛᵤᵣₑₘₑₙₜ}. As a consequence, the difference in the spin population states whilst the spins are at steady state in the field B₀_{ₚᵣₑₚₒₗₐᵣᵢₛₑ} is larger then the difference in the spin population states whilst the spins are at steady state in the field B₀_{ₘₑₐₛᵤᵣₑₘₑₙₜ}. Put in other words, a sample subjected to B₀_{ₚᵣₑₚₒₗₐᵣᵢₛₑ} provides larger net magnetisation than a sample subjected to B₀_{ₘₑₐₛᵤᵣₑₘₑₙₜ}.

The above said, a change in the differences in spin population states that inevitably occurs when switching the static magnetic field from B₀_{ₚᵣₑₚₒₗₐᵣᵢₛₑ} to B₀_{ₘₑₐₛᵤᵣₑₘₑₙₜ}, as discussed above with reference to step 220, is not instantaneous and is, instead, characterised by the longitudinal relaxation time T₁. It will consequently be understood that the advantages achieved in net-magnetisation at the B₀_{ₚᵣₑₚₒₗₐᵣᵢₛₑ} field strength is retained for some time after having switched the static magnetic field to B₀_{ₘₑₐₛᵤᵣₑₘₑₙₜ}, as discussed above with reference to step 220. It is this advantage that allows obtaining higher signal strength from exposing the spins to B₀_{ₘₑₐₛᵤᵣₑₘₑₙₜ} than would normally be available from spins exposed to B₀_{ₘₑₐₛᵤᵣₑₘₑₙₜ} in a steady state. Consequently, NMR measurements can be undertaken using a B₁ field with a resonant frequency determined by B₀_{ₘₑₐₛᵤᵣₑₘₑₙₜ}, for a time following the switching from B₀_{ₚᵣₑₚₒₗₐᵣᵢₛₑ} to B₀_{ₘₑₐₛᵤᵣₑₘₑₙₜ} that is governed by the T₁ relaxation time of the spins. The small norm of B₀_{ₘₑₐₛᵤᵣₑₘₑₙₜ} of ˜1 mT allows the B₀_{ₘₑₐₛᵤᵣₑₘₑₙₜ} magnetic field to have a low absolute inhomogenity, but a large relative inhomogeneity. Consequently, loss through signal dephasing in there herein disclosed projected field configuration can be avoided. This allows for the norm of the longitudinal magnetization to be proportional to the norm of B₀_{ₚᵣₑₚₒₗₐᵣᵢₛₑ} and not B₀_{ₘₑₐₛᵤᵣₑₘₑₙₜ}, which can be made arbitrarily small, as long as the adiabatic switching is made within a period much shorter than T₁, and for the frequency of precession/signal-readout to be chosen to be proportional to B₀_{ₘₑₐₛᵤᵣₑₘₑₙₜ}. It is desirable for the adiabatic switching to be completed as quickly as possible, albeit without violating Peripheral Nerve Stimulation regulations. In one embodiment, the adiabatic switching from B₀_{ₚᵣₑₚₒₗₐᵣᵢₛₑ} to B₀_{ₘₑₐₛᵤᵣₑₘₑₙₜ} is finished in a time frame that is less than the shortest longitudinal relaxation time T₁ of all of the spin species from which NMR signal is to be acquired. Adiabatic switching between the two fields may involve a gradual reduction of the field B₀_{ₚᵣₑₚₒₗₐᵣᵢₛₑ} accompanied by a gradual increase in B₀_{ₘₑₐₛᵤᵣₑₘₑₙₜ}. In one embodiment NMR signals are acquired from the point in time where B₀_{ₚᵣₑₚₒₗₐᵣᵢₛₑ} has been fully ramped down and B₀_{ₘₑₐₛᵤᵣₑₘₑₙₜ} has been fully ramped up for a period of time that is shorter than the shortest longitudinal relaxation time T₁ of all of the spin species from which NMR signal is to be acquired. In another embodiment NMR signals are additionally acquired after the shortest longitudinal relaxation time T₁ of all of the spin species from which NMR signal is to be acquired has passed and until the end of a longer or of the longest longitudinal relaxation time T₁ of another species of spins of the spin species from which NMR signal is to be acquired. Thereafter, a further measurement cycle can be started by re-activating the field B₀_{ₚᵣₑₚₒₗₐᵣᵢₛₑ} to, again, prepolarise the spins to be examined.
In an alternative embodiment the field switching is not adiabatic. Instead, the field B₀_{ₚᵣₑₚₒₗₐᵣᵢₛₑ} is reduced to a non-zero value in a timeframe that does not allow for a re-distribution of the spin distributions generated at the full strength of B₀_{ₚᵣₑₚₒₗₐᵣᵢₛₑ}. Once the field B₀_{ₚᵣₑₚₒₗₐᵣᵢₛₑ} is sufficiently small, for example 10% of its full strength, B₀_{ₘₑₐₛᵤᵣₑₘₑₙₜ} is activated rapidly, whilst B₀_{ₚᵣₑₚₒₗₐᵣᵢₛₑ} is deactivated equally rapidly. In this manner, the magnitude of the magnetisation generated through B₀_{ₚᵣₑₚₒₗₐᵣᵢₛₑ} is not only maintained but the magnetisation also starts precessing about B₀_{ₘₑₐₛᵤᵣₑₘₑₙₜ} without the need to apply a B₁ excitation pulse.

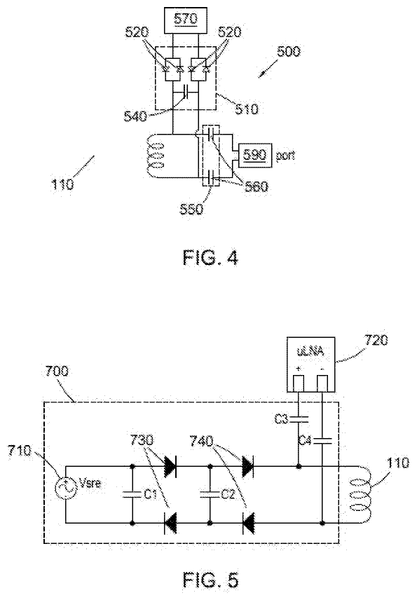

FIG. 4 illustrates an example of a network 500 that can be used for connecting the dual use coil 110 of an embodiment to a prepolarising driver 570 for generating the prepolarising field B₀_{ₚᵣₑₚₒₗₐᵣᵢₛₑ} and, alternately, switching the dual use coil 110 into receive mode. As can be seen from the figure, the network 500 does not comprise any active component and instead is a passive network.

The connection 510 to the prepolarising driver comprises two pairs of cross-coupled diodes 520 connected between each terminal of the dual use coil 110 and a respective port to the prepolarising driver. Also provided is a capacitor 540 across the terminals leading to the port for the prepolarising driver. The capacitor 540 forms a low pass filter with a cut off frequency below the frequencies of magnetic resonance signals the system 100 is designed to generate or receive to prevent higher frequency signals that may be generated by the driver 570 from propagating to the coil 110. In an embodiment, this low pass may be omitted if no high frequency is expected to come from the driver 570 and the port's input impedance is sufficiently high to avoid changing the resonance behaviour of the coil 110. In this manner, whilst direct currents can be provided to the dual use coil 100 from the port connectable to the prepolarising driver via the diodes 520, magnetic resonance signals are also prevented from leaking to the prepolarising driver. The cross-coupled diodes 520 moreover permit signals with amplitudes higher than the diodes' threshold voltage to pass (i.e. the signals creating B₀_{ₚᵣₑₚₒₗₐᵣᵢₛₑ}). whilst blocking lower amplitude signals, such as received magnetic resonance signals and creating a very high impedance path/filter when the coil is in reception mode, removing or at least mitigating noise generated by driver 570.

On the receive side 550 two capacitors 560 prevent direct current and large DC voltages applied to the dual use coil via the connection/network 510 from being applied to the receive chain 590. In a further embodiments further cross-coupled diodes may be provided to connect the terminal of each of the two capacitors 560 that is connected to the receive port to ground. In this manner, whilst low amplitude magnetic resonance signals received using the dual use coil 110 would progress to the receive port, any higher amplitude signal spikes that may be caused by a prepolarising current applied to the dual use coil 110 or by the currents switching flanks, is conducted to ground.

FIG. 5 illustrates another example of a network 700 that can be used for connecting the dual use coil 110 of an embodiment to a prepolarising driver 710 for generating the prepolarising field B₀_{ₚᵣₑₚₒₗₐᵣᵢₛₑ} and, alternately, switching the dual use coil 110 into receive mode and permitting NMR signals received by the dual use coil 110 to be transmitted to the low noise amplifier 720. The circuit illustrated in FIG. 5 also only comprises passive components. As shown in FIG. 5, the circuit comprises diodes 730. Whilst single diodes are shown connected to the terminals of the prepolarising driver 710 in an alternative embodiment a pair of cross-coupled diodes may instead be provided for each terminal in the manner illustrated in FIG. 4. Each of the two further diodes 740 comprises a parasitic capacitance. The total capacitance presented to the dual use coil 110 determines, together with the inductance of the coil 110, its resonance frequency. It is desirable in the embodiment to ensure that the resonance frequency of the coil 110 is above but does not occur at or near the NMR frequencies that are to be observed. The capacitor C2 is in series connection with the parasitic capacitances of the diodes 740, thereby presenting a low overall capacitance to the dual use coil 110. This results in a high resonance frequency of the coil 110.

The diodes 730 and 740 present a high impedance to NMR signals received by the dual use coil 110, to present signal leakage into the prepolarising coil driver 710. In an alternative embodiment, the diodes 730 can be replaced by inductors, depending on the desired cut-off frequency of the network connecting the prepolarising driver 710 with the dual use coil 110. In an alternative embodiment the diodes are replaced by a parallel LC tank circuit that is tuned to the operational frequency.

As will be appreciated from the above, the passive isolation of the prepolarising driver from the receive chain and vice versa is possible because of the difference in operating frequencies of the two branches as well as the different signal amplitudes used (which intrinsically turn the diode switches on and off).

The use of coil 110 under reception mode, past the passive switch (i.e. the DC-blocking capacitors and the diodes protecting the reception stage) can be interfaced with any normal reception electronics desired, depending on frequency. This is because in an embodiment where the nodes of the coil only touch the cross-coupled diodes and the DC block capacitor, the coil acts substantially as any other reception coil in NMR/MRI, and can therefore be tuned and matched, made resonant at one or more frequencies or simply connected directly to an amplifier, for example.

In another embodiment, the diodes 730 and 740 may be replaced by simple active switches that can interrupt the connection of the driver 710 from the coil 110.

### Magnetic Core of the Dual Use Coil

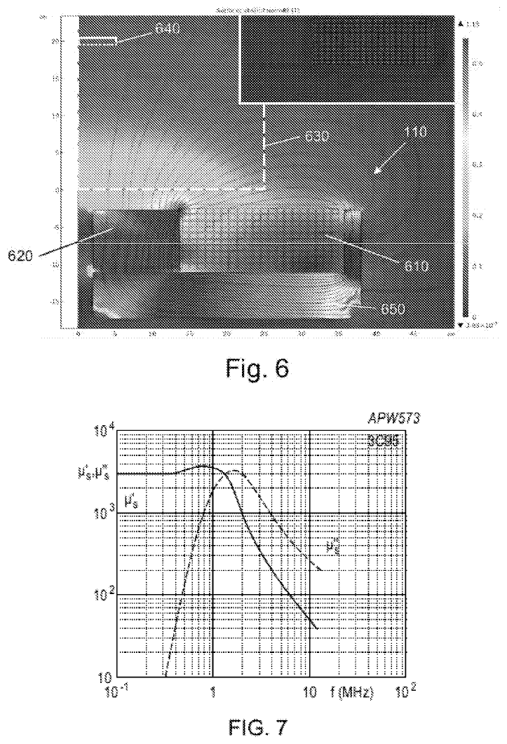

FIG. 6 illustrates a cross section of an axisymmetric simulation of a dual use coil 110 of an embodiment. The dual use coil 110 of the embodiment is rotationally symmetric about an axis that coincides with the ordinate of FIG. 6. It will consequently be appreciated that only the rightmost half of the cross-section of the dual use coil 110 is shown in FIG. 6. The dual use coil 110 comprises windings 610, forming a solenoid coil. Further provided is a magnetic core 620 at the centre of the solenoid. In the embodiment, the magnetic core is cylindrical. Also shown in FIG. 6 are the results of a simulation of the static magnetic field B₀_{ₚᵣₑₚₒₗₐᵣᵢₛₑ} generated by the dual use coil 110. In this simulation, the magnetic core 620 is comprised of a ferrite compound. High B values (approx. 0.5 T) show the rough outline of the ferrite material. Current density in the coil windings is shown on the inset image, highlighting the cross section of individual copper windings. In one embodiment the individual coil windings are themselves made of a litz cross-section/litz wire.

This magnetic core 620 acts as a flux concentrator for concentrating the magnetic flux generated by the solenoid 610 in the area 630 to be occupied by a patient during use and in particular in the field of interest 640 up to approximately 20 cm above the upper surface of the dual use coil 110. The magnetic core 620 has a high magnetic permeability to both the quasi-static magnetic field B₀_{ₚᵣₑₚₒₗₐᵣᵢₛₑ} and to high frequency magnetic fields generated in the region of interest 630 during use of the dual use coil 110. It will be appreciated that the frequency of the magnetic resonance signals generated in the region of interest 630 is dependent on the strength of the magnetic field B₀_{ₘₑₐₛᵤᵣₑₘₑₙₜ}. The strength of the field B₀_{ₘₑₐₛᵤᵣₑₘₑₙₜ}, in turn, depends on the geometry of and the current applied to the coil 120. In one configuration, the frequency of the magnetic resonance signal may be on the order of 200 kHz, although different centre-frequencies can also be imagined. In one embodiment, a centre frequency of about 40 kHz may be used.

If the losses generated by mμ′/mμ″ are of a lower order of magnitude as those introduced by the coil resistance R, ω̅L/R (i.e. in the absence of the magnetic core), it increases the overall Q-value of the dual use coil for the magnetic resonance signal frequency range. The choice of the material for the magnetic core 620 is consequently important. In one embodiment, the magnetic core 620 is made of a soft ferromagnetic material, such as ferrite, for example Ferroxcube 3c95. FIG. 7 shows the real and imaginary permeability, μ′ and μ″ respectively, of this material. The real permeability μ′ contributes to the inductance achievable with a coil using the material as its core and the imaginary permeability μ″ contributes to the magnetic losses of the material. As such, the material is chosen to maximise real permeability μ′ whilst keeping the imaginary permeability μ″ low over a frequency range from 0 Hz to the maximum frequency of the NMR signal that is to be received using the coil. It is, moreover, desirable for the saturation field of the material to be higher than the field generated at the coil core/in the material, when B₀_{ₚᵣₑₚₒₗₐᵣᵢₛₑ} is generated at a predetermined point in the volume of interest/target volume. The conductivity of ferrite may be sufficiently low to not carry eddy currents or only eddy currents with a small amplitude. Consequently, the amount of induction losses suffered during reception is limited in this embodiment. In one embodiment eddy current flow within the ferrite is further reduced by segmenting the ferrite into a plurality of smaller parts that are electrically insulated with respect to each other.

The use of the magnetic core 620 supports a strong field amplification of the magnetic field used for polarization. The resulting increase in B₀_{ₚᵣₑₚₒₗₐᵣᵢₛₑ} increased the available magnetic resonance signal linearly, as will be appreciated from the discussion above. The presence of the magnetic core 620 moreover increases the receive sensitivity of the coil 610. This in turn improves signal reception without appreciably increasing noise in the signal. In one embodiment, this technique is used together with other MRI-required peripherals (e.g. gradient coils) with the effect of the core on the gradient magnetic fields being either accounted for in design or post-processing or with their effect being countered by corrective procedures (e.g. a shim-like procedure for the gradient fields).

By using a core the magnetic field generated by the coil (or its sensitivity to magnetic resonance signals) can be directed towards a desired volume of interest. Conversely, it allows to prevent field being generated in areas outside of the coil that are of no interest to the magnetic resonance measurement or that may even be a potential source of interference. The core may therefore be used to shape the magnetic field/sensitivity of the coil and be used as or expanded to act as a magnetic shield. In this manner, the prepolarising field can be directed only toward the patient/designated measurement volume of the coil, therefore reducing potentially harmful or at least undesirable fringe field in the rest of an examination room.

It will be appreciated that, whilst a particular geometry for coil 610 and magnetic core 620 are shown in FIG. 6, these geometries are not essential and other coil and core geometries may instead be chosen. More generally, but without wishing to be bound by theory, the magnetic core 620 advantageously is located at a distance from the field of interest 640 that is less than the largest dimension of the receive coil (i.e. the coil diameter in the FIG. 6 example). In this manner, an amplification of RF sensitivity can be achieved in the field of interest, when compared to a coil of equal geometry but omitting the ferromagnetic core. In other embodiments, the shape of the magnetic core may be non-cylindrical. For example, in one embodiment, the core may have a frustoconical shape, with a smaller one of the two circular faces of the frustum facing the volume of interest. In other embodiments, the core shape is not symmetrical or not rotationally symmetrical. In one embodiment, the shape of the core is irregular and may have been obtained as the result of a numerical design optimisation process of the core and/or coil shape to maximise the magnetic field strength per unit sqrt Watt achieved by the coil and core combination in a volume of interest.

In addition to the magnetic core 620 shown in FIG. 6, in one embodiment the dual use coil 110 further comprises a shield 650. In the embodiment shown in FIG. 6, the shield is provided such that it surrounds the solenoid 610 and the magnetic core 620 on all sides that are not facing the region of interest 630, i.e. a region on which a patient may be placed for nuclear magnetic resonance examination. In this manner, leakage of fringe magnetic fields can be supressed. The shield 650 can be made of soft ferromagnetic material. Although FIG. 6 illustrates a shield that is a continuous structure, surrounding the solenoid 610 on three sides, it will be appreciated that this structure is not essential. Instead, the shield 650 can be provided on fewer sides, for example only on the side of the solenoid 610, that is opposite the region of interest 630 or only on one or more sides surrounding the solenoid 610. In another embodiment, the shield 650 can be made of multiple parts that are either joined to each other or held in a fixed relationship relative to each other by means of fixing elements, without, however, fixedly joining individual components of the shield 650 directly to each other. Simultaneously, the use of the magnetic core below and to the side of the reception coil also created a directional selectivity of the signal, projecting the field into a predetermined volume of interest where only field lines coming from dipoles roughly above the coil/in the volume of interest manage to create a flux variation in the centre of the coil and therefore induce a voltage in the coil. This can be understood through the reciprocal field of the coil. A coil creating a negligible field in a location will also mean a dipole in that location cannot induce an appreciable voltage in the coil, for the same dipole amplitude.

In another embodiment, a further, thinner shield is provided surrounding the shield 650 shown in FIG. 6 to the sides and below. This further shield further reduces stray fields outside of the volume of interest and increases the safety of the system. In one embodiment, this further shield extends vertically higher than the patient facing face of the coil 110, so that stray fields to the side of the volume of interest are also shielded. In one embodiment, the further shield is detachable from the coil 110 and/or shield 650.

In portable NMR systems, magnetic shielding is especially important as there is less control over the surrounding environment. Many jurisdictions impose a safety 625 exclusion zone around operating NMR systems. This zone is typically defined by the contour at which the fringe field has decayed to 5 Gauss (0.5 mT). Legislation aside, magnetic field strengths greater than 5 Gauss can adversely affect surgical implants, such as pacemakers, which is, of course, undesirable.

Embodiments of the NMR system which make use of electromagnets, as opposed to persistent superconducting magnets or permanent magnets, are advantageous because they do not have a fringe field in their de-energised state. This facilitates transportation.

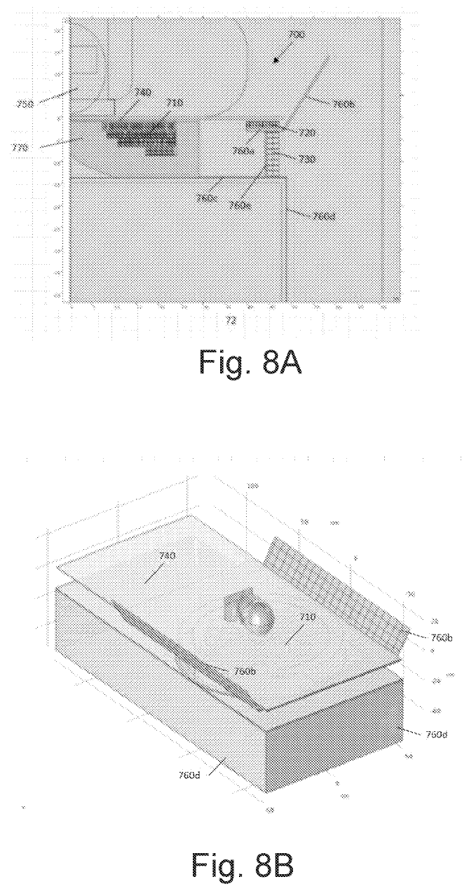

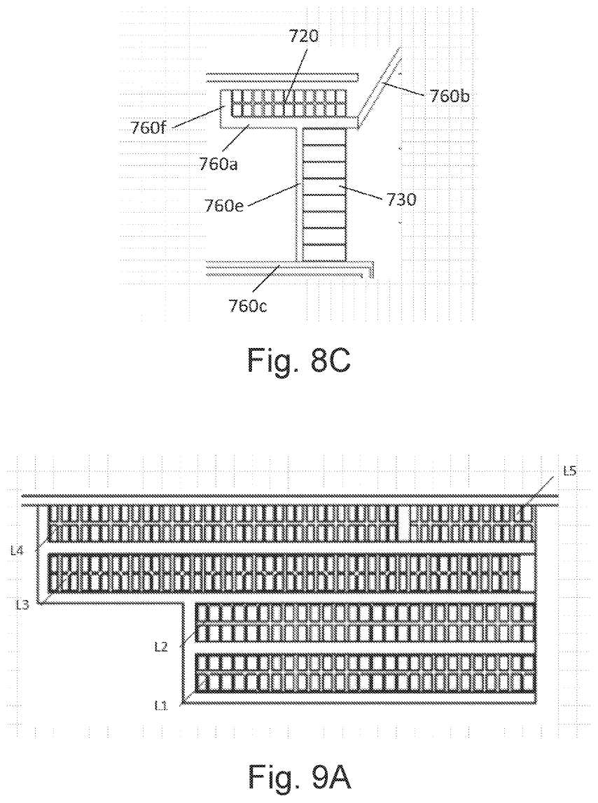

FIG. 8a is a schematic illustration, showing half a cross-sectional view of an axisymmetric NMR system according to an embodiment. The NMR system 700 includes a dual use coil 710 with a magnetic core 770, a counter coil 720, an active noise cancellation (ANC) coil 730 and a magnetic structure 760. In the embodiment shown, the NMR system 700 further includes a bed 740 upon which a patient to be tested can lie within the image volume 750. FIG. 8b shows a 3-dimensional isometric projection of an NMR system according to an embodiment, similar to that shown in FIG. 8a but comprising flaps 760b that extend along part of the length of the patient bed, with a patient's head positioned in the central field of the dual use coil 710. FIG. 8c shows a close-up view of part of the NMR system shown in FIG. 8a. As shown in FIG. 8a, the central part of the magnetic 770 core is hollow in approximately the lower half of the core's thickness. Providing a high permeability material in this area provides little or no benefit to the operation of the dual use coil but would add undesirable weight. In one embodiment this space is filled with a material that has a thermal conductivity exceeding that of the material of the magnetic core 770.

### Dual Use Coil 710

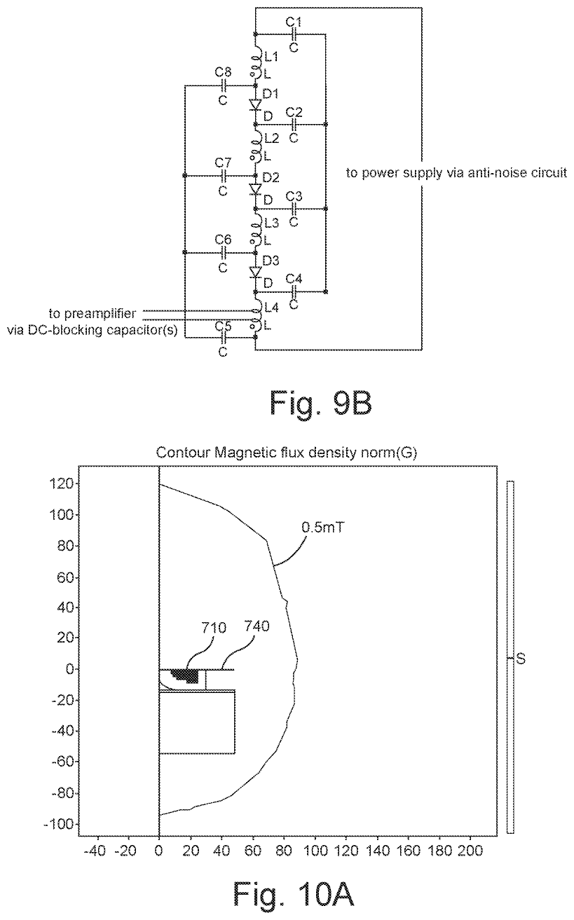

As has already been set out in detail above, the dual use coil 710 is operated under DC conditions for prepolarisation and under AC conditions for receiving the NMR signal. However, since the optimal parameters for a coil for prepolarisation and for receiving the NMR signal can differ, the dual use coil 710 is separated into multiple parts (L1, L2, L3, L4 and L5) in one embodiment, as shown in FIG. 9a.

FIG. 9b illustrates a circuit for connecting the parts L1 to L4 of another dual use coil 710 to a power supply and to a preamplifier respectively. The dual use coil of FIG. 9b does not comprise L5. However, the inductor L5 of the dual use coil illustrated in FIG. 9a is connected in the same manner shown for inductors L1 to L3 in FIG. 9b. The circuitry in FIG. 9 is connected to a power supply (not shown) via an anti-noise circuit. Anti-noise circuits are known to the skilled reader, for example from FIG. 8 and the accompanying description of U.S. Pat. No. 4,906,931 (the entirety of which is incorporated herein by this reference).

In some embodiments, each coil (L1, L2, L3, L4) comprising the dual use coil 710 has comparable parameters (e.g., radii, winding tums, material, etc.). It will be appreciated that the invention is not so limited and that, alternatively, some or all of the coils may have different parameters, such as different radii, different thickness along their axis of rotational symmetry, different number of winding turns, different materials. In addition, the height of individual windings/wire thickness can differ within a coil. It is moreover emphasised that, although dual use coils with four or five sub-coils are shown in the embodiments, the invention is not so limited and instead a different number of sub-coils may be used to form the dual use coil.

### DC Operation

As shown by the circuitry in FIG. 9b, each coil (L1, L2, L3, L4) is connected in series via respective diodes (D1, D2, D3) so that a DC current can pass through each of the coils. The coils (L1, L2, L3, L4) can therefore function to generate the static prepolarising field. The mutual inductive coupling between coils (L1, L2, L3, L4), depends on the coil design, but is typically strong. For the purposes of DC operation the capacitors C1 to C8 can be considered to have a high impedance or even represent an open circuit.

### AC Operation

For AC operation, the impedance of the diodes to the very small signals received by the inductors is of such magnitude that they can be considered substantially non-conductive. As will be clear to the person skilled in the art, for AC operation, the circuit shown in FIG. 9b is reduced to a circuit whereby each inductor (for example L4) is connected in series with two capacitors (C4 and C5 for conductor L4) on either end thereof and where the four resulting series CLC circuits are connected to each other in parallel. This parallel connection ensures that the effective inductance of the dual use coil 710 during AC reception is far lower than its effective inductance during DC operation. This increases the self-resonance frequency of the coil but does not reduce the sensitivity of the receive section even when the diodes are open.

For the purpose of receiving the NMR signal, a part of, or a whole of, one of the coils (e.g., L4) is used. A capacitor (not shown) is connected in parallel with this coil in order to tune it to a resonance at the operation frequency. This tuning requires the self-resonance of the dual use coil 710 be greater than the operation frequency. Meeting this requirement is within the capabilities of the skilled reader.

The NMR signal received by the coil (i.e., L4) is then fed through DC-blocking capacitors to a preamplifier. Optionally, the preamplifier is noise-matched and the NMR signal is further fed through a filtering network and/or a blanking switch. In one embodiment, a switched damping or detuning circuit is connected between the common node of capacitors (C1, C2, C3, C4) and the common node of capacitors (C5, C6, C7, C8) to shorten ringdown of currents induced in the coils (L1, L2, L3, L4) during excitation pulses.

A part of, or a whole of, one of the coils (e.g., L3) can also be used for excitation. If the same part of the coil is used for excitation and for sensing (in the illustrated example L4), a T/R switch is connected to the same port of the coil (i.e., L4) after the DC-blocking capacitors and a controller is used to control a reverse bias applied to the diodes to ensure that conduction during excitation pulses is minimised. In a different embodiment a different part of the coils is used for excitation than is used for receiving and circuitry that isolates a transmitter chain from the coil in a receive mode and circuitry that isolates a preamplifier from the coil in a transmit mode are provided. In an alternative embodiment circuits that actively cancel transmit signal that has leaked into the receive chain is used to isolate the transmit chain and preamplifiers.

### Counter Coil 720

In some embodiments, the NMR system includes a counter coil 720 to reduce the magnetic footprint of the dual use coil 710 by compensating for the fringe field generated by the dual use coil 710. In the embodiment shown in FIG. 8a, the counter coil 720 is wound concentrically around the dual use coil 710.

Preferably, the magnetic dipole moment of the counter coil 720 is configured to be the same or similar to that of the dual use coil 710, albeit of opposing sign. This can be achieved through control of the radil and number of windings. In some use cases, however, the upper limit for this radii is limited by physical constraints (e.g., available space). The counter coil 720 is then able to, at least partially, cancel the fringe magnetic field generated by the dual use coil 710 when equal and opposite currents are supplied to the coils 710, 720.

In some implementations, the magnetic field profile of the dual use coil 710 varies with time. Preferably, the magnetic field produced by the counter coil 720 exhibits the same time-varying profile in order to effectively compensate for the fringe field. In one embodiment, the dual use coil 710 and counter coil 720 are connected in series so that the current amplitude supplied to each coil at any given time is identical. In such implementations, the input power is divided between the coils 710, 720 in dependence on their relative resistances. As signal quality improves with larger magnetisations, the resistance of the counter coil 720 is, preferably, minimised so that the power drawn by the dual use coil 710 can be maximised. In one embodiment, the wires used for the windings of the counter coil 720 have a larger cross section than those of the dual use coil 710, thereby reducing the counter coil resistance. In an alternative embodiment, the counter coil 720 has fewer windings than the dual use coil 710 to reduce its resistance. In another embodiment, the counter coil 720 has fewer windings and a larger wire cross section than the dual use coil 710.

In one embodiment, the counter coil 720 and dual use coil 710 are concentric with one another so that their dipole vectors coincide. The coils 710, 720 may have the same or different shape, when viewed in plan. For example, they may be circular, polygonal or the like.

It is further desirable that the region of interest 750 be shielded from the magnetic field generated by the counter coil 720 so as not to reduce the prepolarising field for the measurement. Embodiments of the NMR system include a magnetic structure 760 which is configured to shape the magnetic field profile of the counter coil 720 in a way that guides the flux away from the region of interest 750. Further details of the magnetic structure 760 are provided below.

### Magnetic Structure 760

The magnetic structure 760 comprises various components that magnetically couple to the magnetic core 770 of the dual use coil 710. As will be understood, the magnetic structure 760 concentrates magnetic flux within its volume, thereby influencing the paths of flux lines in other parts of the NMR apparatus, the field of view or free space. As discussed above, the counter coil 720 is configured to generate a static magnetic field that, in the fringes of the static magnetic field generated by the dual use coil 710, is substantially equal and opposite to the static magnetic field generated by the dual use coil 710 to thereby cancel or at least reduce the fringes of the static magnetic field generated by the dual use coil 710. By providing a low resistance magnetic flux path, in particular through the plate 760a shown below the counter coil 720 and the flap 760b shown on an outside of the counter coil 720 when viewed relative to the region of interest 750, the flux lines generated by the counter coil 720 are focused towards and outside of the counter coil 720 when viewed relative to the region of interest 750 (ROI)/imaging volume. In this manner, the counter coil 720 can produce a field that reduces/counteracts the fringe field generated by the dual use coil 710 whilst the negative/destructive influence of the field generated by the counter coil 720 in the ROI is reduced to an acceptable level.

In an embodiment, the magnetic structure 760 further comprises an upper casing 760c that helps in reducing the generation of a static magnetic field below it, one or more casing sides 760d and/or an annular inner magnetic structure 760e provided on an inside of ANC coil 730. Individual use of any of components 760a to 760e in the absence of any of the other components 760a to 760e is expressly contemplated. Moreover, it is expressly contemplated that components 760a and 760b are used in combination with each other as described above but without components 760c to 760e. In an embodiment, component 760c connects the magnetic core 770 to the other components of the magnetic structure 760.

FIG. 8c shows a further beneficial modification to the magnetic structure 760 of an embodiment. As shown in FIG. 8c, a further annular core 760f is provided inside of the counter coil 720. This further annular core 760f serves to further reduce the field strength produced by the counter coil 720 in the ROI.

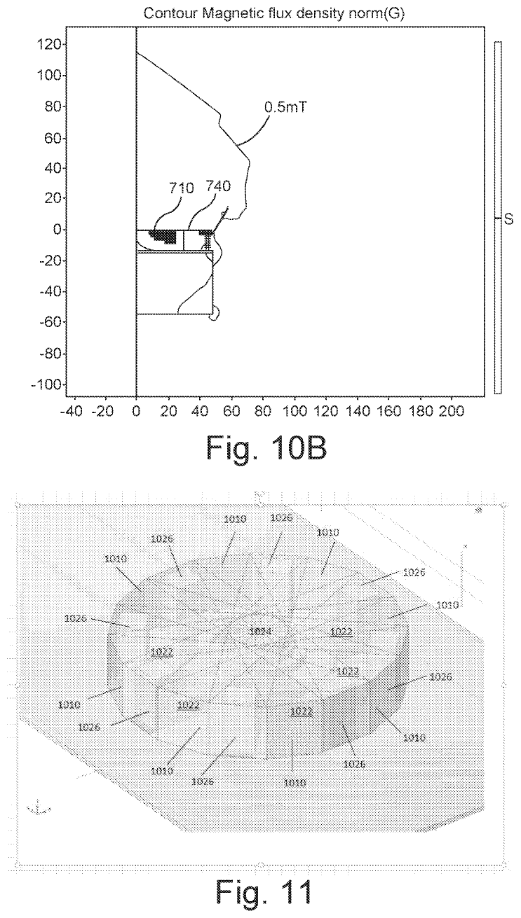

FIGS. 10a and 10b illustrate cross sections of a 2-dimensional axisymmetric simulation of the safety exclusion zone (as defined by the 5G or 0.5 mT contour) for embodiments of the NMR system with (FIG. 10b) and without (FIG. 10a) the counter coil 720. In FIG. 10a, the magnetic structure 760 consists only of the magnetic core 770 carrying the dual use coil, whereas in FIG. 10b the magnetic structure 760 further comprises components 760a to 760e and the counter coil 720.

As can be seen by comparing FIGS. 10a and 10b, the approximate radius of the safety exclusion zone decreases from around 90 cm to 70 cm. In both simulations, the total power consumption was fixed at 4000 KW and the counter coil drew less than 300 W. Embodiments of NMR system that include the counter coil 720 and magnetic structure 760 can, therefore, reduce the footprint of the fringe field significantly at modest cost to power consumption.

Referring back to FIG. 8b, it can be seen that a flap portion 760b of the magnetic structure extends along at least part of each long edge of the patient bed 740. Each flap portion 760b can extend along the entirety of the long edge of the bed or along a part thereof. In a preferred embodiment, a flap portion 760b that does not extend along the entire length of the patient bed 740 extends the same length on either side of a vertical centre line of the dual use coil 710.

In some embodiments, each flap portion 760b is foldable between an extended position for use (as shown in FIG. 8b) and a stowed away position for transit and to provide access for the patient to the patient bed. As can be deduced from FIG. 8a, the width of the system is reduced from around 1.2 m to around 1 m in the stowed away position. This helps to improve manoeuvrability of the system through doorways, corridors, elevators and the like, which is important for portable NMR systems. In the extended position the flap portions 760b extend upward and outward from the patient bed 740.

In some embodiments, each flap portion 760b weighs less than 10 kg, more preferably less than 5 kg, so that a single operating person can move the flaps 760b between extended and stowed away positions.

Embodiments of the NMR system which include a magnetic structure 760 with foldable flap portions 760b may require a gap between that portion 760b and the remainder of the magnetic structure 760 to allow for the folding motion. In embodiments with a gap width of less than 1 cm the effect the gap has on performance is acceptable. In some embodiments, there may exist gaps between other parts of the magnetic structure 760. In some embodiments the width of these gaps is less than 1 cm, causing the effect the gaps have on performance to be acceptable.

In a specific embodiment, the magnetic structure 760 is made from a ferrite compound. Other materials with a high magnetic permeability are, however, possible. Parts of the magnetic structure, for example the magnetic core 770 carrying the dual use coil 710 and the magnetic structure 760, are composed of the same or different magnetic material. For example, in one embodiment, different parts 760a to 760e of the magnetic core 760 may be made of different ferrite materials. More generally, the parts 760a to 760e of the magnetic core 760 may comprise any combination of the same or different high-permeability materials. In this manner the choice of material and in particular the permeability of the material can be matched to the technical requirements of the component for which the material is used. The material choice therefore allows using cost effective materials for components with less strict permeability requirements.

In some embodiments, the magnetic structure 760 is an assembly of parts that are coupled together for use. This decreases the cost of manufacturing and improves ease of assembly. Each part in turn can be composed of one or more sub-parts. In one embodiment, the core 770 carrying the dual use coil 710 is, for example, made of a plurality of components that are electrically insulated against each other. In one embodiment an insulating layer between individual components extends in a radially extending plane that includes the longitudinal axis of the dual use coil 710. Optionally, the parts (or sub-parts) of the magnetic structure 760 and/or the core 770 are coated with an electrically resistive layer to restrict conduction between adjacent components, thereby limiting the size of possible eddy current loops.

### Coil Cooling and Thermal Management

The strength of the field B₀_{ₚᵣₑₚₒₗₐᵣᵢₛₑ} increases with the amplitude of the current used in the dual use coil 110 when the dual use coil 110 is used to generate the prepolarising field B₀_{ₚᵣₑₚₒₗₐᵣᵢₛₑ}. Given that higher B₀_{ₚᵣₑₚₒₗₐᵣᵢₛₑ} field strength provides a larger available difference in the populations of the spin states and consequently a larger available magnetic resonance signal, it follows that it is desirable to use as high a current as is possible in the dual use coil 110 to generate the B₀_{ₚᵣₑₚₒₗₐᵣᵢₛₑ} field. The use of high currents will lead to a temperature increase of the dual use coil 110 through resistive heating. In embodiments, the dual use coil 110 can benefit from active cooling to further increase the direct current that can be applied to it. Other coils, for example the counter coil 720, the ANC coils 730, and the PCB used for imaging pulses, present in some embodiments, also benefit from thermal management.

In particular, over the course of an imaging measurement, resistive heating can, if left unmanaged, increase the temperature of the coils to a point at which performance is adversely affected. Other components, such as the magnetic structure 760 or the bed 740 of the system, may also be adversely affected by and/or even exacerbate heating.

In some embodiments, the permeability and power loss for the magnetic structure 760 and core 770 is temperature dependent. In embodiments with ferrite-compound based magnetic structures 760 or core 770, heat outflow is restricted by the relatively poor thermal conductivity of the ferrite-compounds, to the extent that the magnetic structure 760 and core 770 act as a barrier to heat outflow. It is, of course, of utmost importance that the temperature experienced by the patient on the bed 740 is maintained at a safe and comfortable level. A thermal management system, either making use of passive cooling elements and/or active cooling elements is, therefore, desirable.

In some embodiments, the NMR system includes one or more heat exchanger, as active electrical and/or mechanical elements, to remove heat away from the coils and the bed. Such active elements may be located so that any EMI noise or eddy current back fields produced by consequence of the extractor(s) are, at least partially, shielded by the magnetic structure 760. In one embodiment, the heat extractor(s) are enclosed or partially enclosed by the magnetic structure 760. In one embodiment, the heat extractor(s) are located beneath the bed, inside an electronics box, optionally on an aluminium plate.

Preferably, the active elements are placed sufficiently far away from the coil and bed that their effect on the NMR output signal is minimised. This said, the dimensions of the NMR apparatus may not make this possible. In such situations it is advantageous to place the active elements within an enclosure for magnetic shielding, such as an enclosure formed by magnetic components 760c and 760d. Further details of this enclosure are provided below. One or more passive cooling elements with high thermal conductivity are then arranged to direct heat towards those active elements. Example passive cooling elements are provided below, but any material exhibiting high thermal conductivity but negligible electrical conductivity and magnetic permeability can be used.

FIG. 11 is a schematic illustration of an interdigitated arrangement for the passive cooling element 1010 and the magnetic structure 1020 of the NMR system, according to an embodiment. The magnetic structure 1020 comprises a plurality of radially extending portions 1022 which extend from the magnetic core 1024 in a star shape and respective 880 upwardly extending tail portions 1026 which depend from radially distal ends of portions 1022. The passive cooling element 1010 is arranged to occupy the spaces between portions 1022 and 1026. The interdigitated arrangement facilitates effective heat transfer away (i.e., downwards) from the bed. Although the active cooling elements are not shown in FIG. 10, it will be understood that the passive cooling elements extend from the coils (e.g., the dual use coil) to the active elements and away from the bed. It will be 885 appreciated that, whilst an arrangement with 8 extending portions 1022 is shown in FIG. 11, different numbers of extending portions and associated tail portions 1026 are equally possible and envisaged.

While the discretised nature of the magnetic structure 1020 around its 890 circumference causes a flux concentration in areas immediately above the portions 1026, it was found that local flux concentration of this nature nevertheless does not cause inhomogeneity of the prepolarising field in the ROI or imaging volume 750 that negatively affects performance. The performance of the dual use coil 710 for receive purposes remains equally unaffected.

The interdigitated arrangement shown in FIG. 11 moreover makes more efficient use of thermally conductive material, in terms of volume, weight and cost, than an approach whereby the entire magnetic structure and dual use coil are surrounded.

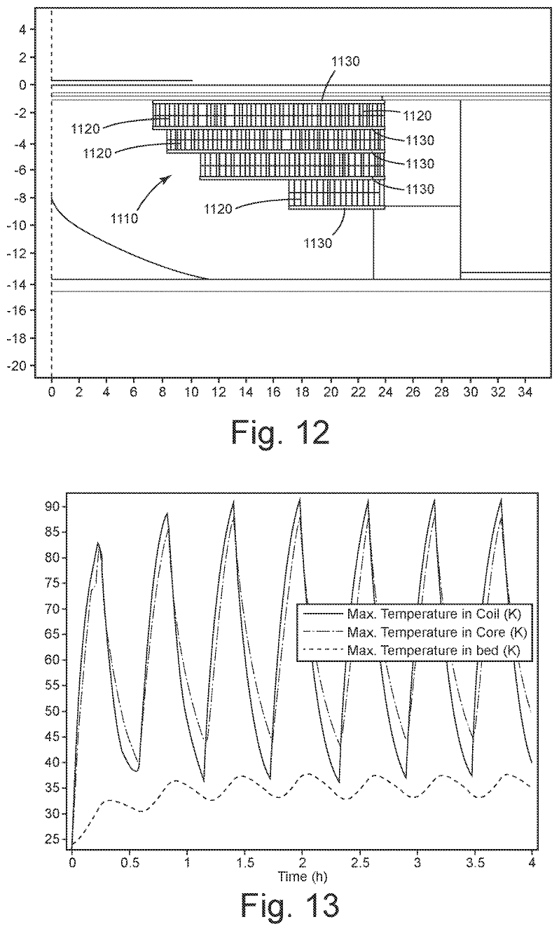

FIG. 12 is a schematic illustration that shows a cross section of the dual use coil 1110, according to an embodiment. As has already been described, the dual use coil 1110 comprises a plurality of separate coils 1120. As shown, these coils are spaced apart from one another by a respective passive cooling layer 1130. These layers serve to draw heat away from sections of the coil, which would otherwise require heat conduction through the coil itself. The thickness of these layers is selected according to the required heat outflow and the volume allocated to the dual use coil 110 in the NMR system. When used in combination with the embodiment illustrated in FIG. 11, the layers 1130 are connected to the thermally conducting structure of FIG. 11 in a highly thermally conductive manner.

In some embodiments, the passive cooling elements 1110 of FIG. 11 and/or layers 1130 of FIG. 12 are made of thermally conductive ceramics, such as aluminium nitride, boron nitride, alumina or a combination thereof.

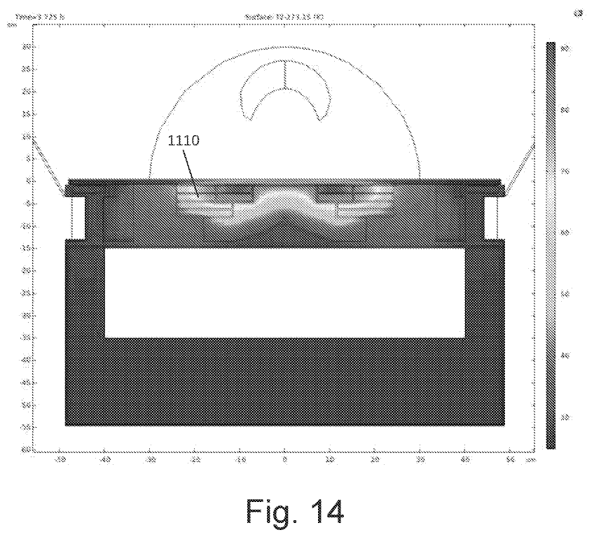

FIG. 13 shows a simulated temperature profile of the bed, magnetic structure and dual use coil 1110 over the course of 7 measurement cycles, for an NMR system operating with a 3860 W polarization coil, 140 W counter-coil, and the interdigitated arrangement shown in FIG. 11 and further comprising the passive cooling layers 1130 shown in FIG. 12. The simulation also accounted for the duty cycle of the system, since the NMR system is envisaged to operate with downtime between measurements. As shown, after 3 measurement cycles, the system achieves an equilibrium whereby the temperature reaches the same maximum value on each subsequent measurement cycle. Room temperature is assumed to be 24° C. The temperature on the surface of insulation covering the bed reaches a maximum of 38° C., which is within safety limits, while temperatures inside the coil 1110 and magnetic structure remain within acceptable limits. FIG. 14 shows the temperature distribution of the simulated NMR system shown in FIG. 13 at time=3.725 hr, which coincides with the maximum temperature for the last simulated measurement cycle. Hot spots are seen to develop inside the dual use coil 1110 but temperatures drop off, showing the effectiveness of the arrangement in FIGS. 11 and 12 to remove heat out from the system.

Other ways of actively cooling the dual use coil are envisaged. In one embodiment, the conductor that forms the windings of the dual use coil 110 is located, preferably concentrically, inside the tubing. Cooling fluid is pumped through the tubing to remove excess heat. In another embodiment, the coil windings are made of electrically conductive tubing, such as copper tubing, through the lumen of which cooling fluid can be pumped/can flow. In yet another embodiment the dual use coil 110 may be submerged in a fluid tight container through which cooling fluid is circulated. Windings of the dual use coil 110 may be spaced apart from each other to allow penetration of cooling fluid between the windings. In one embodiment, any coolant that evaporates is captured and cooled/condensed back into liquid form before being re-supplied to a container holding the dual use coil 110 and the coolant.

### Active Noise Cancellation (ANC) Coil 730

In some embodiments, the NMR system includes one or more ANC coils 730. In the embodiment shown in FIG. 8a, the system includes one ANC coil 730. The ANC coil(s) 730 are configured to have maximal sensitivity to distant sources of noise (i.e., those in the far field) while having minimal sensitivity to the region of interest 750. It will be appreciated that, because the ANC coil 730 shown in FIG. 8a surrounds the dual use coil 710, the ANC coil 730 can detect unwanted external noise emanating from any direction around the dual use coil 710 from which the dual use coil 710 is likely to pick up noise. The background noise measured at the ANC coil 730 can then be subtracted from the measured NMR signal, taking into account sensitivity scaling factors, in order to more accurately determine the actual NMR signal.

It will be understood that noise in this context includes any coherent electromagnetic interference (EMI) source that is detectable by the ANC coil(s) 730 and the detection portion of the dual use coil 710. It does not, however, include incoherent noise sources, such as Johnson noise from the coils themselves.

The relative sensitivity of the coils to signal and noise sources as a function of that source location can be simulated or measured. The scaling coefficient a for the background noise is given by the ratio of reciprocal fields of the ANC coil 730 at the location of the noise source (S^{b}). The scaling coefficient β for the signal from the patient is given by the relative sensitivity of the ANC coil to the NMR signal produced by the patient (S^{p}).

That is, for the simplified case where there are three coils: two detector coils (denoted, in this example, main and head, which may, for example, be coils L3 and L4 from FIG. 9b, although any available detection coil may be used, on its own or in combination with other detection coils, such as the dual use coil) and one ANC coil 730:

$$α = \frac{{s}_{ANC}^{b}}{{s}_{main}^{b} + {s}_{Head}^{b}} ; β = \frac{{s}_{ANC}^{p}}{{s}_{main}^{p} + {s}_{Head}^{p}} ;$$

For effective noise subtraction from the measured NMR signal, the system is ideally designed so that α>1 and β<1. That is, the ANC coil 730 is configured to be more sensitive to background noise (far field sources) than the detection coil 710, but configured to be less sensitive to the NMR signal from the patient. It will be appreciated that, in the above equations, the ratios a and B are expressed with reference to the sum of sensitivities in the denominator, the sensitivity of the dual use coil 710 or other detection coil may be expressed differently in this context, depending on the electrical configuration of the dual use coil or any other detection coil.

It can be shown that, for a single background noise source, subtracting the signal detected by the ANC coil 730 from the signal detected by the main and head detector coils eliminates the background noise, but reduces the signal by a factor equal to

$$( 1 - \frac{β}{α} ) .$$

At the same time, including an ANC coil 730 into the system for the purpose of subtracting background noise introduces incoherent noise (e.g., Johnson noise) to the NMR signal measurement, intrinsic to the ANC coil 730 itself. The Johnson noise, N, is equal to \sqrt{4kTR}, where T is the absolute temperature, k is the Boltzmann constant and R is the resistance of the coil. It can be shown that the fractional increase in incoherent noise

$$\frac{N ( after )}{N ( before )} ,$$

is equal to

$$\sqrt{1 + \frac{Z}{α}} ,$$

where Z is

$$\frac{{T}_{ANC} {R}_{ANC}}{{T}_{Main} {R}_{Main} + {T}_{Head} {R}_{Head}} .$$

The fractional increase can therefore be minimised by configuring the ANC coil(s) 730 with a resistance that is much smaller than the detector coil(s) of the dual use coil 710. Passive cooling elements 1010, described in more detail elsewhere, can also be used to ensure the temperature of the ANC coil 730 is kept to a minimum. It is further noted that the fractional increase in incoherent noise of having an ANC coil 730 in the system is reduced if the operating temperature of the dual use coils 710 increases (all else unchanged).

When comparing an NMR system with the ANC coil 730 with an ideal system without background noise and limited only by Johnson noise (of the detector coils), it can also be shown that the signal-to-noise ratio (SNR) decreases to a value of

$$( 1 - \frac{β}{α} ) / \sqrt{1 + \frac{Z}{α}}$$

times that of the ideal system.

That said, as the background EMI signal power is expected to be much larger than the additional Johnson noise power for the ANC coil, the elimination of the coherent background noise leads to an overall improvement in the SNR of the NMR signal. In most cases, a loss of 1-10% of the SNR caused by the Johnson noise of the ANC coil 730 will be less than the loss caused by background EMI noise.

Similar to the counter-coil 720, the magnetic core 770 carrying the dual use coil at least partially shields the ANC coil 730 from the region of interest 750 and the flap portions 760b help to guide magnetic flux from the image volume 750 away from the ANC coil 730. In an embodiment, the ANC coil 730 is arranged beneath the flap portion 760b and exterior to the magnetic structure 760. Optionally, the ANC coil 730 is wound concentrically around the dual use coil 710. The far field sensitivity of the ANC coil 730 then has a similar spatial profile to the dual-use coil 710, albeit preferably with a scaling factor α>1.

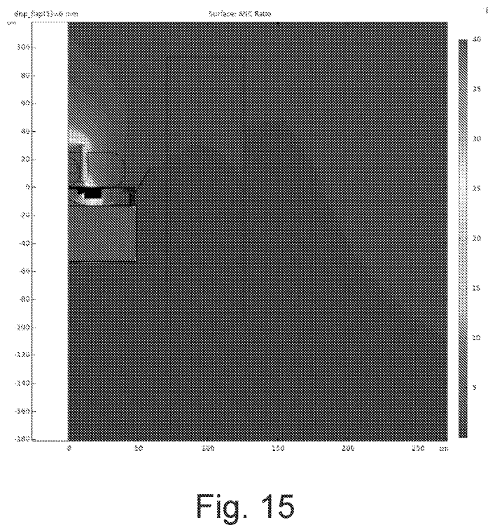

FIG. 15 shows the result of a simulation of coil sensitivity spatial profiles, according to an embodiment including two detector coils (the dual use coil and an additional coil placed on the head of the simulated patient) and one ANC coil 730. The ratio of SNR from these two detection coils and from the ANC coil is plotted, i.e., 1/α. As desired, in the region of interest 750, the ratio is much larger than 1, whereas outside that volume, the ratio drops rapidly to a value much less than 1. This demonstrates that the placement of the ANC coil 730 exterior to the magnetic structure and beneath the flap portions 760b is a highly effective configuration. This is also demonstrated by the fact that, in areas shielded from the ANC coil 730, including in the shielded housing below the core 770 and element 760c, the ratio is much larger than 1 signifying that the ANC coil 730 is substantially less sensitive to fields from these areas.

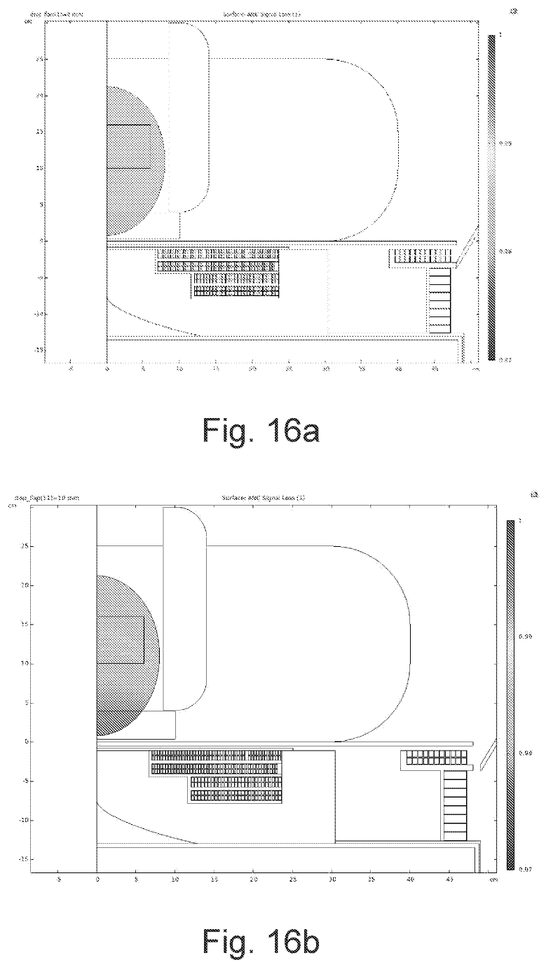

In some embodiments, a gap is present adjacent to the flap portion 760b of the magnetic structure. This gap acts as a channel through which magnetic flux from the region of interest 750 can impinge upon the ANC coil 730 and thereby increase the sensitivity ratio, β. It has been found that, despite this increase in β caused by the gap, the overall decrease of the SNR for the NMR signal is acceptable, at least for gaps of 1 cm or less. FIGS. 16a and 16b show the result of a simulation of the SNR loss factor

$$( 1 - \frac{β}{α} ) / \sqrt{1 + \frac{Z}{α}}$$

for the NMR signal, according to an embodiment without (FIG. 16a) and with (FIG. 16b) such a gap. In the simulation, a coherent noise source was positioned 4 metres above the bed 740 in the system. This direction of the noise source placement above the bed gives the worst SNR performance. As can be seen, the SNR without a gap is reduced to about 98.5% of its original value after ANC subtraction, whereas a gap of 1 cm decreases the SNR to 97.8% of its original value. As above, background EMI signal power is expected to be significant and so the elimination of the coherent background noise leads to an overall improvement in the SNR, with or without the gap being present.

In some embodiments, the ANC coil 730 includes its own magnetic core, distinct from the magnetic structure. In other embodiments, annular portion 760e of the magnetic structure, which are described further herein, forms part of the magnetic core carrying the ANC coil 730.

In some embodiments, the NMR system includes a plurality of ANC coils (not shown). This helps to improve cancellation of EMI noise, since each ANC coil can then be configured to detect different coherent sources (e.g., noise sources at different locations). It is envisaged, for example, that such ANC coils could be arranged in different locations within the NMR system and/or at different inclinations relative to the primary axis of the dual use coil 710 in order to improve their collective sensitivity for far-field noise sources. In some embodiments, the position and inclination of each of the plurality of ANC coils may be adjustable to optimize collective sensitivity to the observed far-field noise sources.

### Eddy Current Mitigation

As has been already been described in detail above, the operation sequence of the NMR system includes energising and de-energising (ramping down) a dual-use coil 710 to switch on and off a prepolarising field. Preferably, the ramping down of the prepolarising field to zero happens fast enough that the NMR measurement can be taken with minimal loss of spin polarisation. However, rapid changes in magnetic field (on the order of 10 T/s or more) can result in peripheral nerve stimulation, causing pain or discomfort to the patient. The maximum ramp rates, for a given maximum magnetic field strength within the patient, are known to the skilled reader. In any case, intermediate ramp down rates still lead to significant back action fields caused by the eddy currents that develop on electrically conductive objects close to the coil 710 upon switching.

The presence of electrically conductive objects in the NMR system is unavoidable as the system is controlled electronically. While it is preferable that the electronics be kept away from the coils, this is, at least to an extent, at odds with a compact and portable NMR system.

The back-action field, or back field, from these eddy currents adversely affects NMR measurements if: (1) the amplitude of the back field, in the region of interest, is comparable to, or larger than the amplitude of the holding field, B₀_{ₘₑₐₛᵤᵣₑₘₑₙₜ}; and/or (2) the gradient of the back field within any given voxel of the region of interest is comparable to, or larger than the ambient or shimmed inhomogeneity of the holding field with the relevant gradients applied. This is because (1) the back field modifies the magnetic resonance frequency in an unpredictable and time-varying way, making NMR results less accurate, and (2) gradients in the back field can cause spin dephasing and loss of magnetization.

In some embodiments, the NMR system further comprises a passive coil that is arranged in-between the dual-use coil 710 and an electrically conductive object upon which eddy currents are expected to develop. The passive coil may simply be a conductive loop positioned between the source of the magnetic field and an object that would carry developed eddy currents in the absence of the passive coil. Because of the back field generated by induced currents in the passive coil, the object that would carry developed eddy currents in the absence of the passive coil experiences a reduced change in field strength. Any eddy currents induced in this object will therefore be reduced when compared to a scenario where the passive coil is not present. From the perspective of the conductive object, the passive coil therefore slows the change in field amplitude from the dual-use coil caused by switching and the amplitude of induced eddy currents in the conductive object is thereby reduced. It is preferable to induce the eddy currents in the passive coil instead because the eddy currents can be more easily controlled. Various ways of controlling the eddy currents are envisaged. As an example, the eddy currents could be caused to decay more quickly through control of the resistance of the passive coil, up to and including an open circuit configuration. In some embodiments, the system comprises more than one of these passive coils.

In one embodiment, the coil is a band of metal, as opposed to a thinner wire arrangement, in order to increase the cross section of the coil and hence the efficacy of its inductive response. Example metallic materials include copper, aluminium or alloys thereof.

In some embodiments, the NMR system further includes the additional active counter-coil for mitigating eddy currents. The configuration whereby the additional active counter coil and dual use coil 710 are connected in series is especially advantageous because the time-variations in magnetic field can be better compensated. The induced eddy currents on electrically conductive objects in these reduced field regions will, in turn, be reduced. In embodiments with the magnetic structure 760 and active counter coil, a further passive coil is unnecessary. That said, the combination of counter coil 720 and passive coil is especially effective at mitigating the effects of back action fields from eddy currents and is adopted in one embodiment. In one embodiment the above discussed counter coil 720 is used to additionally provide the function of the active counter coil.

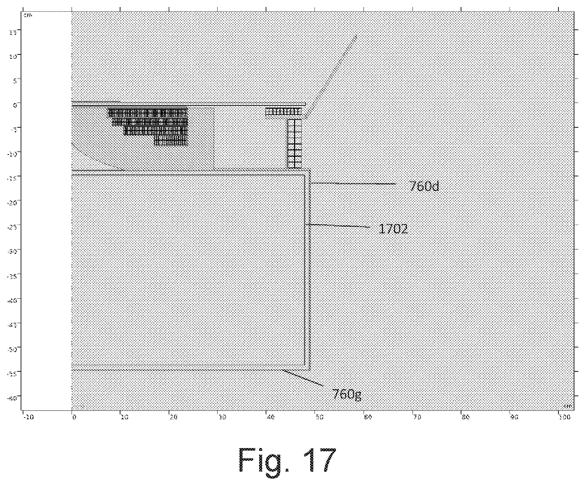

In some embodiments, a metal enclosure 1702 is employed to screen magnetic fields and noise within the detection bandwidth of the NMR system between the electronics and receiving portion of the dual use coil. In one embodiment, the metal enclosure 1702 is located beneath the dual use coil 710 for this purpose, and the system electronics housed therein. In an embodiment, the metal enclosure 1702 has at least one open-end so as to provide a partial enclosure for the system electronics. Back action fields from eddy currents developing on surfaces of this metal enclosure are expected. The metal enclosure may be in contact with the magnetic structure 760 or spaced from the magnetic structure by a gap. In some embodiments, as shown in FIG. 17, the magnetic structure 760 at least partially envelops the metal enclosure 1702 in order to guide flux around, but not through, the enclosure via casing sides 760d and casing bottom 760g. This helps to suppress the induction of eddy currents in the enclosure 1702.

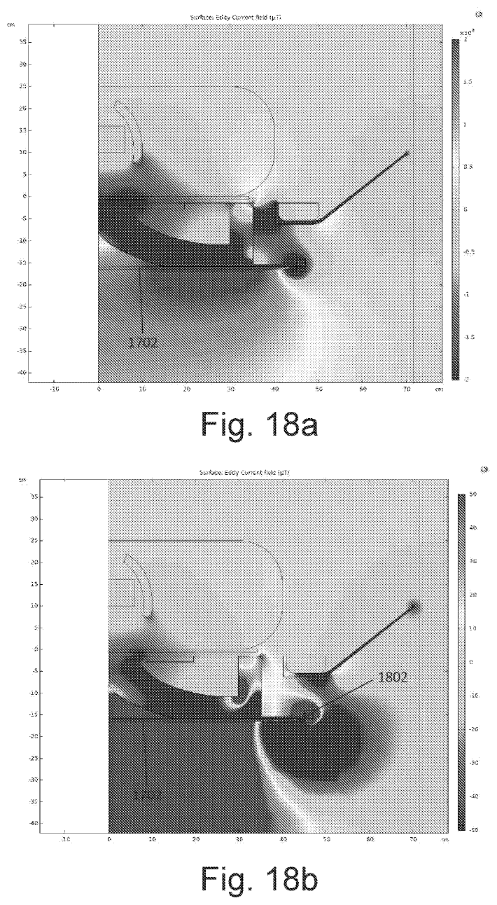

FIGS. 18a and 18b shows the eddy current back field resulting from the casing on 1115 top of the metal enclosure 1702, without and with a passive coil 1802, respectively. As can be seen by comparing the scale bars, the maximum back field in the region of interest 750 in the absence of the passive coil is around 2 mT, and around 50 μT with the passive coil, representing a reduction by around 20 times.

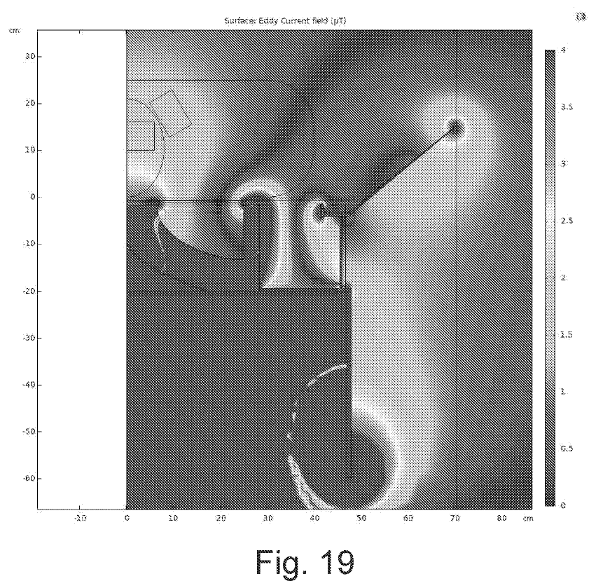

FIG. 19 shows the eddy current back fields simulated in a NMR system, without a counter coil 720 or passive coil 1802. As can be seen, in an embodiment the magnetic structure 760 alone is capable of reducing the back field in the region of interest to less than 4 μT. The magnetic structure 760 (including the core 770) shields the region of interest 750 from the back field and redirects that field elsewhere. It can be appreciated that a properly configured magnetic structure 760 can be more effective at reducing the back field in the region of interest, compared to the use of a counter coil 720 or passive coil 1802. It can be appreciated by comparing FIG. 19 to FIGS. 18a and 18b that the magnetic structure component 760e, present in the embodiment shown in the former but absent in the embodiments shown in the latter, is especially impactful on achieving this reduction.

As mentioned above, in some embodiments the windings of the dual use coil 110 are spaced apart from each other. Whilst this is advantageous in the context of cooling (as discussed above), such spacing between windings is also used and advantageous in uncooled dual use coils 110. This is because by spacing the windings apart from each other the amount of inter-winding parasitic capacitance of the coil is reduced. This in turn increases the self-resonance frequency of the dual use coil 110, allowing the use of a large number of windings whilst keeping the self-resonance frequency of the dual use coil 110 above the frequency of the nuclear magnetic resonance signal.

In a further embodiment, the coil windings are embedded in a solid temperature conducting material. A face of this material, for example the face of the material facing away from the volume of interest, may be connected to a heat sink, preferably an actively cooled heat sink. In one embodiment, solid state cooling is used to provide such active cooling.

The self-resonance frequency of the coil is influenced by the parasitic capacitance of the coil. By reducing ε′ of the dielectric between coil windings the parasitic capacitance of the coil is reduced. By also reducing ε″ electrical losses in the dielectric medium and noise associated with them are further reduced. As such, in an embodiment, a high quality cooling medium flooding the coil or solid material into which the coil is embedded is chosen to reduce electrical losses of the coil.

While certain arrangements have been described, the arrangements have been presented by way of example only, and are not intended to limit the scope of protection. The inventive concepts described herein may be implemented in a variety of other forms. In addition, various omissions, substitutions and changes to the specific implementations described herein may be made without departing from the scope of protection defined in the following claims.

1-19. (canceled)

20. A single-sided nuclear magnetic resonance system having a volume of interest on a patient side thereof and comprising:
a first coil configured to generate a first static magnetic field in the volume of interest;
a second coil configured to generate a second static magnetic field in the volume of interest;
wherein the first static magnetic field is substantially larger than the second static magnetic field.

21. The single-sided nuclear magnetic resonance system of claim 20, configured to adiabatically switch between the first static magnetic field and the second static magnetic field.

22. The single-sided nuclear magnetic resonance system of claim 20, further comprising soft ferromagnetic shielding on at least one side of the coil other than the patient side; wherein the coil comprises a ferromagnetic core surrounded by windings of the coil.

23. The single-sided nuclear magnetic resonance system of claim 20, further comprising a static magnetic field driver, a receive chain and a RF coil.

24. The single-sided nuclear magnetic system of claim 20, further comprising a ferromagnetic core, wherein coil windings of the first coil are wound around the ferromagnetic core.

25. The single-sided nuclear magnetic resonance system of claim 24, wherein the ferromagnetic core comprises a plurality of ferromagnetic components that are electrically insulated from each other.

26. The single-sided nuclear magnetic resonance system of claim 20, wherein the first coil has a first diameter and a first longitudinal axis, the system further comprising a third coil with a third diameter and a third longitudinal axis, wherein the first and third longitudinal axes substantially coincide and wherein the third diameter is larger than the first diameter.

27. The single-sided nuclear magnetic resonance system of claim 26, wherein the third coil is an active noise cancellation coil.

28. The single-sided nuclear magnetic resonance system of claim 26, wherein the first and third coils are arranged so that at a distance from the longitudinal axis that is greater than the third diameter the third coil generates a field that counteracts the field generated by the first coil.

29. The single-sided nuclear magnetic resonance system of claim 28, further configured, to energise and/or de-energise the first and third coil simultaneously.

30. The single-sided nuclear magnetic resonance system of claim 20, further comprising flux guiding components arranged to guide the magnetic flux generated by the third coil away from the longitudinal axes.

31. The single-sided nuclear magnetic resonance system of claim 24, wherein the ferromagnetic core comprises soft ferromagnetic material.

32. A magnetic resonance method comprising:
generating, in single-sided nuclear magnetic resonance system having a volume of interest on a patient side thereof, a first static magnetic field in an area of interest using a coil by applying a current through a first coil;
discontinuing application of the current flowing through the first coil;
generating, in the nuclear magnetic resonance system, a second static magnetic field in the area of interest;
application, in the nuclear magnetic resonance system, of a radiofrequency magnetic field to the area of interest at a frequency based on the strength of the second static magnetic field in the area of interest;
receiving any nuclear magnetic resonance signal generated in the area of interest.

33. The method of claim 32, wherein the current flow through the coil and the generating of the second static magnetic field are such that a switch between the first static magnetic field and the second static magnetic field is adiabatic.

34. The method of claim 32, wherein the first coil has a first diameter and a first longitudinal axis, the system further comprising a second coil with a second diameter and a second longitudinal axis, wherein the first and second longitudinal axes substantially coincide and wherein the second diameter is larger than the first diameter, the first and second coils arranged so that at a distance from the longitudinal axis that is greater than the second diameter, the second coil generates a field that counteracts the field generated by the first coil.

35. The method of claim 32, further comprising flux guiding components arranged to guide the magnetic flux generated by the second coil away from the longitudinal axes.

36. The method of claim 32, further comprising energising the first and second coil simultaneously.

37. A nuclear magnetic resonance system having a volume of interest next to a ferromagnetic core and comprising:
a first coil configured to generate a first static magnetic field in the volume of interest; and
a second coil configured to generate a second static magnetic field in the volume of interest;
wherein the first static magnetic field is substantially larger than the second static magnetic field.
